(19) United States
(12) Patent Application Publication
(10) Pub. No.: US 2024/0292672 A1
(43) Pub. Date: Aug. 29, 2024

(54) DISPLAY PANEL AND DISPLAY DEVICE

(71) Applicant: Visionox Technology Inc., Suzhou (CN)

(72) Inventors: Bowen YANG, Suzhou (CN); Yiming XIAO, Suzhou (CN); Yuan YAO, Suzhou (CN); Haohan ZHANG, Suzhou (CN); Xuejing ZHU, Suzhou (CN); Liusong NI, Suzhou (CN)

(73) Assignee: Visionox Technology Inc., Suzhou (CN)

(21) Appl. No.: 18/626,723

(22) Filed: Apr. 4, 2024

Related U.S. Application Data
(63) Continuation of application No. PCT/CN2023/108839, filed on Jul. 24, 2023.

(30) Foreign Application Priority Data
Aug. 2, 2022 (CN) 202210922415.9

(51) Int. Cl. H10K 59/122; H10K 59/80

(52) U.S. Cl. CPC H10K 59/122; H10K 59/8731

(57) ABSTRACT

A display panel and a display device. The display panel includes an array substrate; an organic layer arranged on a side of the array substrate; a pixel definition layer arranged on a side of the organic layer away from the array substrate and having a slot breaking therethrough; an encapsulation layer arranged on a side of the pixel definition layer away from the array substrate. The encapsulation layer includes an organic encapsulation layer communicated with the organic layer through the slot. The organic encapsulation layer of the encapsulation layer and the organic layer are communicated with each other through the slot, so the gas generated by the organic layer is released through the organic encapsulation layer of the encapsulation layer.

### CROSS REFERENCE

The present disclosure is a continuation of International Application No. PCT/CN2023/108839, filed on Jul. 24, 2023, which claims priority to Chinese Patent Application No. 202210922415.9 entitled “DISPLAY PANEL, METHOD FOR PREPARING THE SAME AND DISPLAY DEVICE” filed on Aug. 2, 2022, both of which are incorporated herein by reference in their entireties.

### TECHNICAL FIELD

The present disclosure belongs to the technical field of an electronic product, in particular to a display panel and a display device.

### BACKGROUND

With an advancement of science and technology, digital display devices, such as smart phones and tablet computers, have been widely used. A display panel is an indispensable human-machine communication interface in a display device. For example, an organic light-emitting diode (Organic Light Emitting Diode, OLED) display panel has advantages of self-luminescence, energy saving and consumption reduction, bendability, good flexibility, etc. The display device that realizes the display does not need a backlight, and has characteristics of fast response speed and good display effect, thereby attracting the attention of users, and is widely used in terminal products, such as smart phones and tablet computers.

Due to limitations of a structure of film layers and materials of existing display panels, some of the film layers of the display panel will produce water vapor under the condition of reliability test and ultraviolet irradiation, which affects the reliability of the display panel.

Therefore, a new display panel, display panel preparation method and display device are urgently needed.

### SUMMARY

The present disclosure relates to a display panel, a display panel preparation method and a display device. The organic encapsulation layer of the encapsulation layer and the organic layer are communicated with each other through the slot, so the gas generated by the organic layer is released through the organic encapsulation layer of the encapsulation layer, that is, excessive water vapor in the organic layer is introduced into the organic encapsulation layer of the encapsulation layer, to prevent a film layer from peeling off or bubbling, and thus improve the reliability and service life of the display panel.

In a first aspect, embodiments of the present disclosure provide a display panel, including: an array substrate; an organic layer arranged on a side of the array substrate; a pixel definition layer arranged on a side of the organic layer away from the array substrate and having a slot breaking therethrough; an encapsulation layer arranged on a side of the pixel definition layer away from the array substrate, wherein the encapsulation layer comprises an organic encapsulation layer, and the organic encapsulation layer and the organic layer are communicated with each other through the slot.

In a second aspect, embodiments of the present disclosure provide a display panel preparation method, including steps of: providing an array substrates; forming an organic layer on a side of the array substrate; forming a pixel definition layer on a side of the organic layer away from the array substrate, and forming a slot across the pixel definition layer on the pixel definition layer; forming an encapsulation layer on a side of the pixel definition layer away from the array substrate, wherein the encapsulation layer comprises an organic encapsulation layer, and the organic encapsulation layer and the organic layer are communicated with each other through the slot.

In a third aspect, embodiments of the present disclosure provide a display device comprising the display panel of any one of the above embodiments.

Compared with the prior art, the display panel provided in the embodiments of the present disclosure includes the array substrate, the organic layer, and the pixel definition layer. As the organic layer is formed by materials such as organic resin, before evaporation of the array substrate, in order to ensure cleanliness of a product, the array substrate that has been provided with the organic layer needs to be subjected to a cleaning process before the evaporation. The organic layer can also absorb water in the cleaning process, and the organic layer will release the absorbed water vapor, small molecule organic matter under the condition of reliability test and ultraviolet irradiation. However, due to the fact that the organic layer is covered by film layers, such as the pixel definition layer and the first electrode layer, the gas generated by the organic layer cannot be released, resulting in bubbling and peeling of the film layer. To solve the above problem, in embodiments, the organic encapsulation layer of the encapsulation layer and the organic layer are communicated with each other through the slot across the pixel definition layer, so the gas generated by the organic layer is released through the organic encapsulation layer of the encapsulation layer, that is, excessive water vapor in the organic layer is introduced into the organic encapsulation layer of the encapsulation layer, to prevent a film layer from peeling off or bubbling, and thus improve the reliability and service life of the display panel.

### BRIEF DESCRIPTION OF THE DRAWINGS

FIG. 1 is a schematic diagram of a structure of a display panel provided in embodiments of the present disclosure;

FIG. 2 is a structure diagram of film layers provided by an embodiment at a part B-B in FIG. 1;

FIG. 3 is a structure diagram of film layers provided by another embodiment at a part B-B in FIG. 1;

FIG. 4 is a pixel layout of the display panel provided in an embodiment of the present disclosure;

FIG. 5 is a structure diagram of film layers provided by an embodiment at a part C-C in FIG. 4;

FIG. 6 is a structure diagram of film layers provided by an embodiment at a part D-D in FIG. 4;

FIG. 7 is a pixel layout of a display panel provided by another embodiment of the present disclosure;

FIG. 8 is a flow chart of a display panel preparation method provided in an embodiment of the present application;

FIG. 9 is a schematic structural diagram of a display panel in a preparation process provided by an embodiment of the present disclosure;

FIG. 10 is a schematic structural diagram of a display panel in a preparation process provided by another embodiment of the present disclosure;

FIG. 11 is a schematic structural diagram of a display panel in a preparation process provided by another embodiment of the present disclosure;

FIG. 12 is a schematic structural diagram of a display panel in a preparation process provided by another embodiment of the present disclosure;

FIG. 13 is a schematic structural diagram of a display panel in a preparation process provided by another embodiment of the present disclosure;

FIG. 14 is a schematic structural diagram of a display panel in a preparation process provided by another embodiment of the present disclosure;

FIG. 15 is a schematic structural diagram of a display panel in a preparation process provided by another embodiment of the present disclosure;

FIG. 16 is a schematic structural diagram of a display panel in a preparation process provided by another embodiment of the present disclosure;

FIG. 17 is a schematic structural diagram of a display panel in a preparation process provided by another embodiment of the present disclosure.

### DETAILED DESCRIPTION

The present disclosure is described in further detail below, in conjunction with drawings and specific embodiments.

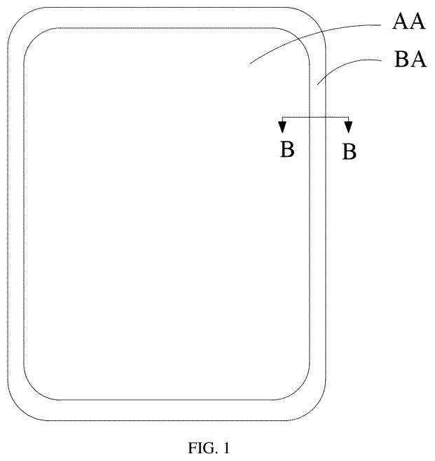

FIGS. 1 to 17 will be combined to describe each embodiment of a display panel, a display panel preparation method and a display device below.

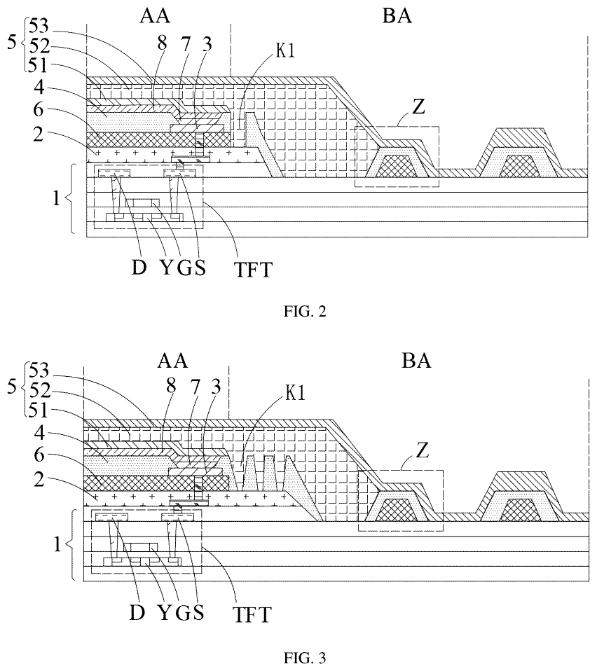

Please refer to FIGS. 1 and 2. Embodiments of the present disclosure provide a display panel, including: an array substrate 1; an organic layer arranged on a side of the array substrate 1; a pixel definition layer 4 arranged on a side of the organic layer away from the array substrate 1; an encapsulation layer 5 arranged on a side of the pixel definition layer 4 away from the array substrate 1. The encapsulation layer 5 and the organic layer are communicated with each other through a slot across the pixel definition layer 4.

The display panel provided in embodiments of the present disclosure includes the array substrate 1, the organic layer, and the pixel definition layer 4. As the organic layer is formed by materials such as organic resin, before evaporation of the array substrate, in order to ensure cleanliness of a product, the array substrate that has been provided with the organic layer needs to be subjected to a cleaning process before the evaporation. The organic layer can also absorb water in the cleaning process, and the organic layer will release the absorbed water vapor and small molecule organic matter under the condition of reliability test and ultraviolet irradiation. However, due to the fact that the organic layer is covered by film layers, such as the pixel definition layer 4 and the first electrode layer 3, the gas generated by the organic layer cannot be released, resulting in bubbling and peeling of the film layer. To solve the above problem, in the embodiments, the organic encapsulation layer 52 of the encapsulation layer 5 and the organic layer are communicated with each other through the slot across the pixel definition layer 4, so the gas generated by the organic layer is released through the organic encapsulation layer 52 of the encapsulation layer 5, that is, excessive water vapor in the organic layer is introduced into the organic encapsulation layer 52 of the encapsulation layer 5, to prevent a film layer from peeling off or bubbling, and thus improve the reliability and service life of the display panel.

As the organic encapsulation layer 52 is also made of organic materials, in the embodiments, the organic encapsulation layer 52 and the organic layer are communicated through the slot, so the gas generated by the organic layer is released through the organic encapsulation layer 52, that is, excessive water vapor in the organic layer is introduced into the organic encapsulation layer 52 to prevent the film layer from peeling off or bubbling.

In the present embodiment, the organic encapsulation layer 52 prepared by the organic material has following advantages. The flatness is better, and the flattening can be realized, which is beneficial to a subsequent growth of an inorganic film layer by methods such as chemical vapor deposition, physical vapor deposition or atomic layer deposition. An organic material with a larger thickness can also be prepared through an existing process, a bending resistance of the organic material is better, and the organic encapsulation layer 52 prepared by the organic material can also improve an encapsulation effect, avoid an erosion of a luminescent material or a wiring of the display panel by water and oxygen, and improve the reliability of the display panel.

The organic encapsulation layer 52 can be molded by IJP (Ink-Jet Printing, i.e., inkjet printing technology).

Optionally, the display panel further includes a first electrode layer 3, and the first electrode layer 3 is located on a side of the organic layer away from the array substrate 1. The first electrode layer 3 includes a plurality of first electrode blocks that are insulated from each other. Specifically, the pixel definition layer 4 is arranged on a side of the first electrode layer 3 away from the array substrate 1. The pixel definition layer 4 has a pixel opening, and the pixel opening exposes at least part of one of the first electrode blocks, so sub-pixel units corresponding to the first electrode blocks illuminate to be displayed through the pixel opening.

In related techniques, a size of each sub-pixel unit is defined by a definition opening of the pixel definition layer (PDL), which is formed by etching. To facilitate etching and peeling, organic materials, such as polyimide, are often used in the pixel definition layer. In order to ensure the cleanliness of the product before the evaporation of the array substrate, it is necessary to carry out cleaning process before the evaporation on the array substrate that has been provided with the pixel definition layer, which will cause the pixel definition layer of organic materials to absorb water, and under the condition of reliability test and ultraviolet irradiation, the pixel definition layer of organic materials will release the absorbed water vapor and small molecule organic matter. And as the pixel definition layer of organic materials is close to an organic light-emitting material, the water vapor released by it will cause a failure of the organic light-emitting material, resulting in the shrinkage of the pixel light-emitting area and affecting the reliability of the display panel.

In order to solve the above problem, in some optional embodiments, the pixel definition layer 4 in the display panel provided by the embodiments of the present disclosure includes at least one inorganic material layer. The inorganic material layer has good water vapor blocking performance, which prevents the pixel definition layer 4 made of organic materials from releasing the absorbed water vapor and small molecule organic matter under the condition of reliability test and ultraviolet irradiation, to ensure the reliability of the display panel.

The pixel definition layer 4 in the present embodiment includes at least one inorganic material layer, and the inorganic material layer has good water vapor blocking properties. Therefore, when the array substrate 1 that has been provided with the pixel definition layer 4 is cleaned before evaporation, the pixel definition layer 4 that includes the at least one inorganic material layer will not have the problem of water absorption, to prevent the absorbed water vapor and small molecule organic matter from being released by the pixel definition layer 4 under the condition of reliability test and ultraviolet irradiation, and ensure the reliability of the display panel. Meanwhile, as the organic layer is formed by the organic material, a problem of water vapor release also arises. In order to solve the problem, the pixel definition layer 4 in this embodiment includes at least one inorganic material layer. And when the first electrode layer 3 is made of metal, the inorganic material layer can be matched with the first electrode layer 3 to prevent the water vapor of the organic layer from transmitting to the organic light-emitting material layer and thereby affecting the organic light-emitting material of the display panel, thus effectively avoiding the problem of shrinkage of pixel light-emitting area after reliability test and ultraviolet irradiation test and improving the reliability and service life of the display panel.

In this embodiment, the pixel definition layer 4 includes the at least one inorganic material layer, that is, the pixel definition layer 4 may include only one inorganic material layer or two inorganic material layers without special limitations. And the inorganic material layer may specifically adopt at least one of silicon nitride, silicon nitride and silicon oxide. Compared with the pixel definition layer 4 of organic materials, such as polyimide, in the prior art, the water and oxygen blocking performance of the inorganic material layer of the pixel definition layer 4 is better, that is, the water oxygen will not enter the inorganic material layer in the cleaning process. Therefore, the inorganic material layer of the pixel definition layer 4 will not absorb water, and the problem that the absorbed water vapor and small molecule organic matter will be released by the pixel definition layer 4 under the condition of the subsequent reliability test and ultraviolet irradiation.

The material of the first electrode layer 3 is generally a material with high work function in order to improve a hole injection efficiency. The material can be gold (Au), platinum (Pt), titanium (Ti), silver (Ag), indium tin oxide (ITO), zinc tin oxide (IZO), transparent conductive polymer (such as polyaniline), etc. In this embodiment, the first electrode layer 3 may specifically adopt an ITO-Ag-ITO stacked structure.

Optionally, the array substrate 1 includes a pixel circuit. The pixel circuit includes a thin-film transistor TFT, and the thin-film transistor TFT includes an active layer Y, a gate G, a source S, a drain D. Materials of the drain D, the source S and the gate G may include one or a combination of molybdenum, titanium, aluminum, copper, etc. The gate G of the thin-film transistor TFT is usually used to receive a control signal to turn on of turn off the thin-film transistor TFT under the control of the control signal. One of the source S and the drain D of the thin-film transistor TFT is connected to the first electrode layer 3.

Referring to FIGS. 2 to 3, in some optional embodiments, the encapsulation layer 5 includes a first inorganic encapsulation layer 51, an organic encapsulation layer 52 and a second inorganic encapsulation layer 53 stacked along s thickness direction of the display panel, and an orthographic projection of the first inorganic encapsulation layer 51 on the array substrate 1 and an orthographic projection of the slot on the array substrate 1 are staggered.

As the first inorganic encapsulation layer 51 is made of inorganic materials and has a good water and oxygen blocking effect, in order to simplify processes, the first inorganic encapsulation layer 51 can avoid the position where a slot will be provided, so the organic layer can be directly communicated with the organic encapsulation layer 52.

The first inorganic encapsulation layer 51 and the second inorganic encapsulation layer 53 can specifically use inorganic materials, such as silicon oxide, silicon nitride, alumina, titanium oxide. The refractive index (compactness) of silicon nitride and alumina is better than that of silicon oxide and titanium oxide, so the water oxygen blocking performance of silicon nitride and alumina is better than that of silicon oxide and titanium oxide.

In some optional embodiments, the display panel has a display area AA and a frame area BA adjacent to the display area AA, and the organic layer, the pixel definition layer 4 and the encapsulation layer 5 extend from the display area AA to the frame area BA. In the frame area BA, the pixel definition layer 4 is provided with a first slot K1 for communicating the organic encapsulation layer 52 with the organic layer.

Because the display area AA usually also includes other film layers arranged in the whole layer, such as the second electrode layer 8 and the like, in order to facilitate the communication between the organic encapsulation layer 52 and the organic layer, the first slot K1 is arranged in the frame area BA of the display panel, so as to facilitate forming of the first slot K1. And the first slot K1 is arranged in the pixel definition layer 4. On the one hand, the organic encapsulation layer 52 and the organic layer can be communicated with each other. On the other hand, the first slot K1 is arranged so that part of the organic encapsulation layer 52 flows into the first slot K1 to block the overflow of the organic encapsulation layer 52.

As shown in FIG. 3, optionally, the cross-section of the first slot K1 along the thickness direction of the display panel can be rectangular, zigzag, etc. without special limitation.

Optionally, the organic encapsulation layer 52 is partially filled into the first slot K1, and when the organic encapsulation layer 52 is formed by IJP (Ink-Jet Printing, i.e., inkjet printing technology), the organic encapsulation layer 52 has a certain fluidity, so when the organic encapsulation layer 52 is formed on the pixel definition layer 4, part of the organic encapsulation layer 52 is automatically filled into the first slot K1 and is in contact with the organic layer.

Optionally, the frame area BA is also provided with a dam part Z, and the first slotted K1 is located on the side close to the display area AA of the first dam part Z close to the display area AA.

In some optional embodiments, the organic layer includes a planarization layer 2, and the planarization layer 2 is made of organic materials, such as organic resin, for improving the flatness of the film layer of the display panel, and facilitating the preparation of film layers, such as the pixel definition layer 4.

Optionally, the organic layer includes a planarization layer 2 and a hole layer 6 that are stacked along the thickness direction of the display panel, both the hole layer 6 and the planarization layer 2 can be made of organic materials, and the hole layer 6 is used for routing signal lines on the one hand, and can also play a certain role in improving the flatness of the film layer on the other hand. In order to facilitate the release of water vapor from the planarization layer 2, in this embodiment, the first slot K1 can also be made to be across the hole layer 6, so the organic encapsulation layer 52 and the hole layer 6 are communicated with each other through the first slot K1 across the pixel definition layer 4.

Optionally, the first slot K1 is arranged around the display area AA, that is, the first slot K1 can be provided along the entire periphery, to increase a contact area of the organic encapsulation layer 52 and the organic layer, improve the water vapor release effect of the organic layer, and also facilitate the communication of the organic layer and the organic encapsulation layer 52 located in different positions.

Optionally, one first slot K1 in the frame area BA is in a continuous annular structure, that is, the first slot K1 is arranged around the entire display area AA. Alternatively, a plurality of first slots K1 can also be arranged to be spaced apart in the frame area BA, that is, a plurality of first slots K1 are individually arranged, respective first slots K1 are arranged to be spaced apart and around the display area AA, to avoid the first slots K1 from adversely affecting the encapsulation effect of the display panel.

In some optional embodiments, the orthographic projection of the first inorganic encapsulation layer 51 located in the frame BA on the array substrate 1 and the orthographic projection of the first slot K1 on the array substrate 1 are staggered.

In order to facilitate the setting of the first slot K1 and avoid the influence of the first inorganic encapsulation layer 51 on the first slot K1, the orthographic projection of the first inorganic encapsulation layer 51 located in the frame area BA on the array substrate 1 and the orthographic projection of the first slot K1 on the array substrate 1 can be staggered. Specifically, the first inorganic encapsulation layer 51 can be indented in the direction toward the display area AA, that is, the first inorganic encapsulation layer 51 does not cover the part of the pixel definition layer 4 that needs to be arranged with the first slot K1, and a part of the pixel definition layer 4 in the frame area is not covered by the first inorganic encapsulation layer 4. Of course, it is also possible to stagger the orthographic projection of the first inorganic encapsulation layer 51 on the array substrate 1 and the orthographic projection of the first slot K1 on the array substrate 1 by other means, such as setting the form of slot, without special limitations.

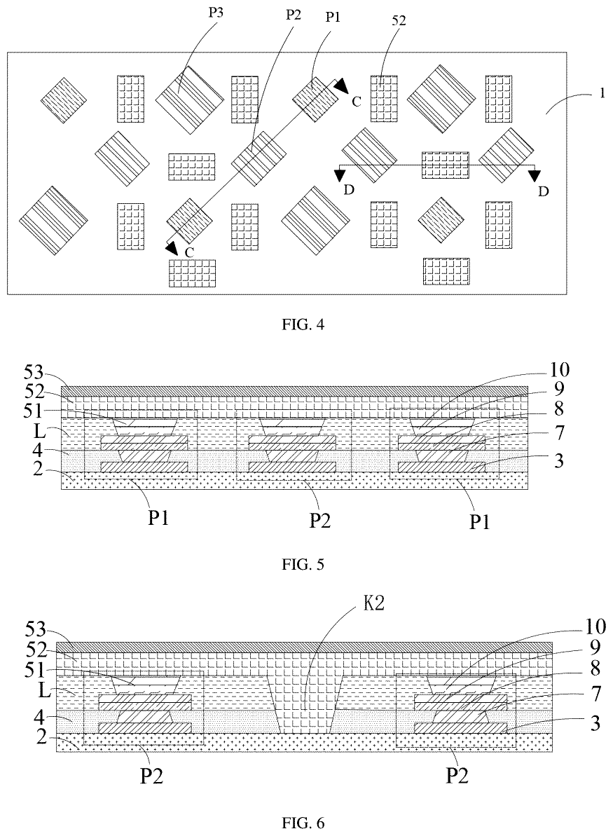

Referring to FIG. 4 to FIG. 6, in some optional embodiments, the display panel has the display area AA and the frame area BA adjacent to the display area AA, and the organic layer, the pixel definition layer 4 and the encapsulation layer 5 all extend from the display area AA to the frame area BA. In the display area AA, the pixel definition layer 4 is provided with a second slot K2 for communicating the organic encapsulation layer 52 with the organic layer, and the orthographic projection of the second slot K2 on the array substrate 1 and the orthographic projection of the pixel opening on the array substrate 1 are staggered. Optionally, the organic encapsulation layer 52 is partially filled into the second slot K2 to be communicated with the organic layer.

In addition to the first slot K1 set in the frame area BA, the second slot K2 can also be set in the display area AA to realize the communication between the organic encapsulation layer 52 and the organic layer. Because the display area AA is provided with sub-pixel units of different colors, the sub-pixel units need to carry out the light-emitting display area AA, so the second slot K2 cannot interfere with the sub-pixel units. And in order to facilitate the forming of the second slot K2, the second electrode layer 8 of the sub-pixel units and film layers, such as the inorganic encapsulation part, corresponding to the sub-pixel units can be patterned, so only the pixel definition layer 4 is arranged between the adjacent sub-pixel units. By staggering the orthographic projection of the second slot K2 on the array substrate 1 and the orthographic projection of the pixel opening on the array substrate 1, the second slot K2 is avoided from affecting the light output of the sub-pixel units in the pixel opening.

In some optional embodiments, an isolation portion L is arranged on a side of the pixel definition layer 4 away from the array substrate 1, and the second slot K2 is across the isolation portion L and the pixel definition layer 4 simultaneously to be communicated with the organic layer.

By setting the isolation portion L to isolate the evaporation material when the light-emitting layer of the display panel is formed, that is, all sub-pixel units formed are independent of each other, so as to avoid the problem that part of the film layer adopts the whole surface evaporation molding, and causes the side conduction between respective sub-pixel units. The second slot K2 is across the isolation portion L to be communicated with the organic layer, that is, the isolation portion L also needs to be provided with the slot to facilitate the communication between the organic layer and the organic encapsulation layer 52.

Optionally, along the thickness of the display panel, the cross-section of the isolation portion L is in at least one of I-shape or T-shape. There is no special restriction on the cross-section of the isolation portion L, as long as the isolating effect to the evaporation material is ensured.

As shown in FIG. 4 to FIG. 6, the display panel further includes the sub-pixel units of different colors. The sub-pixel units are located in the pixel opening. Each sub-pixel unit includes the first electrode block, a light-emitting material layer 7 and a second electrode layer 8 that are stacked. The second slot K2 is arranged between at least some of adjacent sub-pixel units. Optionally, the sub-pixel unit includes a first sub-pixel unit P1, a second sub-pixel unit P2 and a third sub-pixel unit P3. The first sub-pixel unit P1, the second sub-pixel unit P2 and the third sub-pixel unit P3 are any one of three colors of red, blue, green respectively, and the material adopted by the light-emitting material layer 7 can be specifically adjusted to realize the luminescence of different colors. The second slot K2 is arranged between the adjacent sub-pixel units to avoid the second slot K2 from adversely affecting the illumination and display of the sub-pixel units.

Optionally, at least in the display area AA, the first inorganic encapsulation layer 51 includes a plurality of inorganic encapsulation parts arranged to be spaced apart and corresponding to the sub-pixel units, and the orthographic projection of each inorganic encapsulation part on the array substrate 1 and the second slot K2 on the array substrate 1 are staggered.

The first inorganic encapsulation layer 51 can be patterned through processes, such as etching, to form the plurality of inorganic encapsulation parts arranged to be spaced apart, and the inorganic encapsulation parts are arranged corresponding to the sub-pixel units. It can be understood that the orthographic projection of the inorganic encapsulation parts on the array substrate 1 and the orthographic projection of the sub-pixel units on the array substrate 1 at least partially overlap, and the first inorganic encapsulation layer 51 is divided into a plurality of inorganic encapsulation parts to avoid mutual interference between the inorganic encapsulation parts and the second slot K2.

Optionally, the inorganic encapsulation parts are at least partially arranged between adjacent two isolation portions L. And as the inorganic encapsulation parts and the sub-pixel units are correspondingly arranged, the sub-pixel units can be independent packaged through the inorganic encapsulation parts matched with the isolation portions L, and the encapsulation of the display panel is avoided from being affected by the second slot K2, and thus the reliability of the display panel encapsulation is improved. Optionally, in this embodiment, the inorganic encapsulation parts may be located between the adjacent two isolation portions L as a whole, to facilitate the arrangement. A part of the inorganic encapsulation parts can be located between the adjacent two isolation portions L, and a part of the inorganic encapsulation parts can extend to the surface of a side of the isolation portion L away from the array substrate 1, so as to ensure the encapsulation effect.

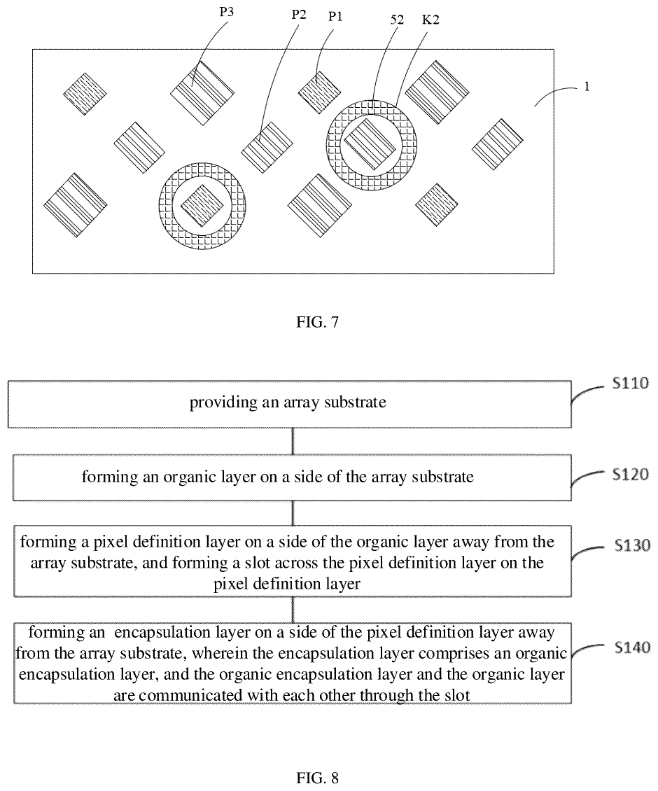

Optionally, as shown in FIG. 7, the pixel definition layer 4 includes only one second slot K2 arranged to form an enclosed annular construction to receive a respective sub-pixel unit, that is, the second slot K2 is in a continuous annular structure, such as a circular or square ring, etc. When the second slot K2 is arranged around the whole sub-pixel unit, the communicating area of the organic encapsulation layer 52 and the organic layer can be effectively increased, and the water vapor release effect of the organic layer is improved.

Of course, at least part of the second slot can be arranged to form an enclosed annular construction to receive a respective sub-pixel unit, that is, the second slot K2 can also be arranged around part of an edge of a respective sub-pixel unit. Or, the pixel definition layer 4 includes a plurality of second slots K2 that are spaced apart can be arranged around the sub-pixel unit, and respective second slots K2 can be set relative to edges at different positions of the sub-pixel unit respectively, so as to avoid the first slot K1 adversely affecting the illumination and display of the sub-pixel unit.

Optionally, a light-adjusting layer 9 and a protective layer 10 are also stacked between the second electrode layer 8 and the first inorganic encapsulation layer 51, and the light-emitting layer 9 can be CPL (cappling layer, light removal layer) mainly to reduce an optical waveguide effect and improve the overall light output performance of the device. The protective layer 10 can be made of LiF (lithium fluoride) material to protect the CPL layer.

Referring to FIG. 8, another embodiment of the present disclosure also provides a display panel preparation method, including following steps:
S110, providing an array substrates 1;
S120, forming an organic layer on a side of the array substrate 1;
S130, forming a pixel definition layer 4 on a side of the organic layer away from the array substrate 1, and forming a slot across the pixel definition layer 4 on the pixel definition layer 4; and
S140, forming an encapsulation layer 5 on a side of the pixel definition layer 4 away from the array substrate 1, wherein the encapsulation layer 5 includes an organic encapsulation layer 52, and the organic encapsulation layer 52 and the organic layer are communicated with each other through the slot.

In this embodiment, the organic encapsulation layer 52 of the encapsulation layer 5 and the organic layer are communicated with each other through the slot, so the gas generated by the organic layer is released through the organic encapsulation layer 52 of the encapsulation layer 5, that is, the excessive water vapor in the organic layer is introduced into the organic encapsulation layer 52 of the encapsulation layer 5, to prevent the film layer from peeling off or bubbling and improve the reliability and service life of the display panel.

In step S110, the array substrate 1 may specifically include a substrate and a pixel circuit formed on the substrate, and the substrate may be a hard substrate, such as a glass substrate; a flexible substrate made of polyimide, polystyrene, polyethylene terephthalate, polyparaxylene, polyethersulfone or polyethylene naphthalate. The active layer Y, the gate G, the source S, the drain D and other film layers of the pixel circuit can be formed by evaporation, photolithography and other processes.

In the step S120, the organic layer can be formed on a side of the array substrate 1 through an evaporation process, and the material of the organic layer can be hexamethyldimethicyl ether, epoxy resin or polyimide (Polyimide, PI), and other silica-based adhesive materials with a light transmittance of more than 90%.

In the step S130, the material of the pixel definition layer 4 can be evaporated on the side of the organic layer away from the array substrate 1, and then the evaporation material can be patterned through processes, such as etching, so the pixel definition layer 4 is provided with the pixel opening and the slot. The pixel opening and the slot can be formed by the same process or can be formed separately without special limitations.

In the step S140, the encapsulation layer 5 includes the first inorganic encapsulation layer 51, the organic encapsulation layer 52 and the second inorganic encapsulation layer 53. As the first inorganic encapsulation layer 51 and the second inorganic encapsulation layer 53 are made of inorganic materials, the first inorganic encapsulation layer 51 and the second inorganic encapsulation layer 53 can be formed by deposition process, and the organic encapsulation layer 52 can be formed by inkjet printing technology. As the pixel definition layer 4 is provided with the slot, the material of the organic encapsulation layer 52 formed by the inkjet printing is filled into the slot to be communicated with the organic layer.

Optionally, a light-emitting layer is arranged on the pixel definition layer 4, the light-emitting layer is at least partially located in the pixel opening, and the isolation portion L is also arranged on the pixel definition layer 4. The isolation portion L is arranged to isolate the evaporation material when the light-emitting layer is formed by the evaporation, that is, all sub-pixel units formed are independent of each other, to prevent part of the film layer from being formed by the whole surface evaporation molding and thereby causing the problem of side conduction between each sub-pixel unit.

The isolation portion L can be made of the same material as the pixel definition layer 4 to reduce production costs.

Optionally, between the step of forming a pixel definition layer 4 on a side of the organic layer away from the array substrate 1 and the step of forming the encapsulation layer 5 on a side of the pixel definition layer 4 away from the array substrate 1, a step is further comprised of: forming a first sub-pixel unit P1 in each pixel opening; forming a first photoresist J1 on a side of at least one of first sub-pixel units P1 away from the array substrate 1; etching the first sub-pixel units P1 not covered by the first photoresist J1; forming second sub-pixel units P2 respectively on a side of the first sub-pixel unit P2 having not been etched away from the array substrate 1 and the pixel opening of the first sub-pixel unit P1 having been etched; forming a second photoresist J2 at a side of at least one of second sub-pixel units P2 located in the pixel opening away from the array substrate 1; etching the second sub-pixel units P2 not covered by the second photoresist J2.

In the embodiment, a photolithography technology is utilized to independently form the first sub-pixel unit P1 and the second sub-pixel units P2, so the second slot K2 is formed between the adjacent first sub-pixel unit P1 and the second sub-pixel unit P2. The thickness of each film layer of the first sub-pixel unit P1 and the second sub-pixel unit P2, such as the light-emitting material layer 7, the second electrode layer 8, etc., can be adjusted separately. For example, thicknesses of second electrode layers 8 of the first sub-pixel unit P1 and the second sub-pixel unit P2 can be different.

Specifically, in the embodiment of the present disclosure, taking the preparation of a the first sub-pixel unit P1, the second sub-pixel unit P2 and the third sub-pixel unit P3 as an example, a preparation method with following steps is provided.

The organic layer and a pixel definition layer 4 that are stacked are provided. The pixel definition layer 4 has three pixel openings, and a first electrode block is formed in each pixel opening.

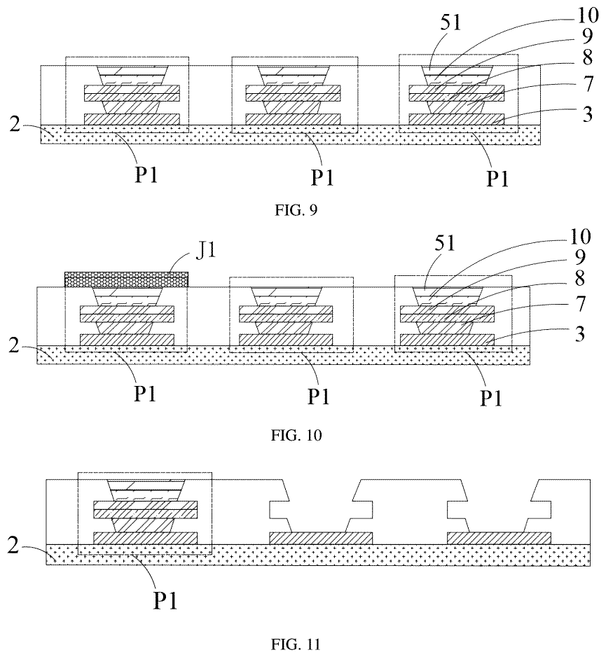

The light-emitting material layer 7, the second electrode layer 8, the light-adjusting layer 9, the protective layer 10 and the inorganic encapsulation part of each first sub-pixel unit P1 are sequentially formed in respective pixel opening, as shown in FIG. 9. Of course, according to an actual situation, the light-emitting layer 9 and the protective layer 10 can be not directly formed at first and the inorganic encapsulation part is formed on a side of the second electrode layer 8, and after the inorganic encapsulation part is formed, the light-adjusting layer 9 and the protective layer 10 can be formed on the side of the inorganic encapsulation part away from the array substrate 1.

The first photoresist J1 is formed on a side of the inorganic encapsulation part that forms any pixel opening of the first sub-pixel unit P1 away from the light-emitting material layer 7, as shown in FIG. 10.

The light-emitting material layer 7, the second electrode layer 8, the light-emitting layer 9, the protective layer 10 and the inorganic encapsulation part of the first sub-pixel in the pixel opening not covered by the first photoresist J1 are etched and removed, as shown in FIG. 11.

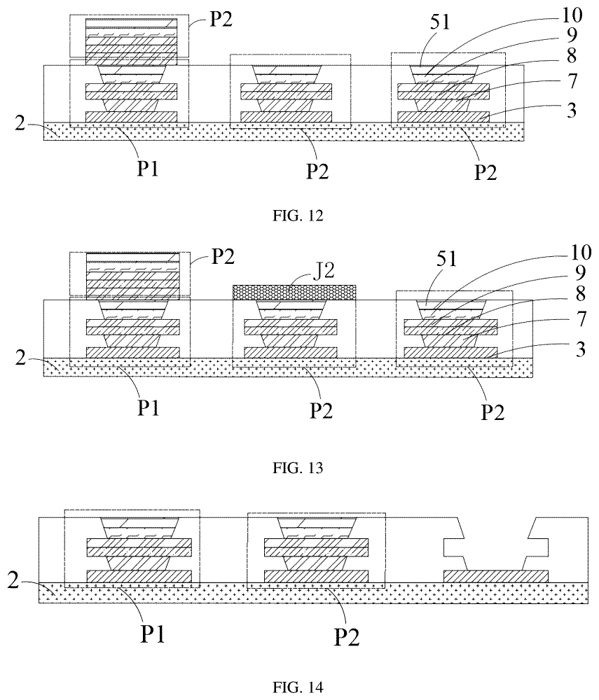

The first photoresist J1 is removed. And the light-emitting material layer 7, the second electrode layer 8, the light-emitting layer 9, the protective layer 10 and the inorganic encapsulation part of the second sub-pixel P2 are formed on each of a side of the inorganic encapsulation part of the first sub-pixel unit P1 away from the light-emitting material layer 7 and another two pixel openings, as shown in FIG. 12.

The second photoresist J2 is formed on a side of the inorganic encapsulation part away from the light-emitting material layer 7 in any pixel opening that is only provided with the second sub-pixel unit P2, as shown in FIG. 13;

The light-emitting material layer 7, the second electrode layer 8, the light-adjusting layer 9, the protective layer 10 and the inorganic encapsulation part of the second sub-pixel unit P2 in the pixel opening not covered by the second photoresist J2 are etched and removed, as shown in FIG. 14.

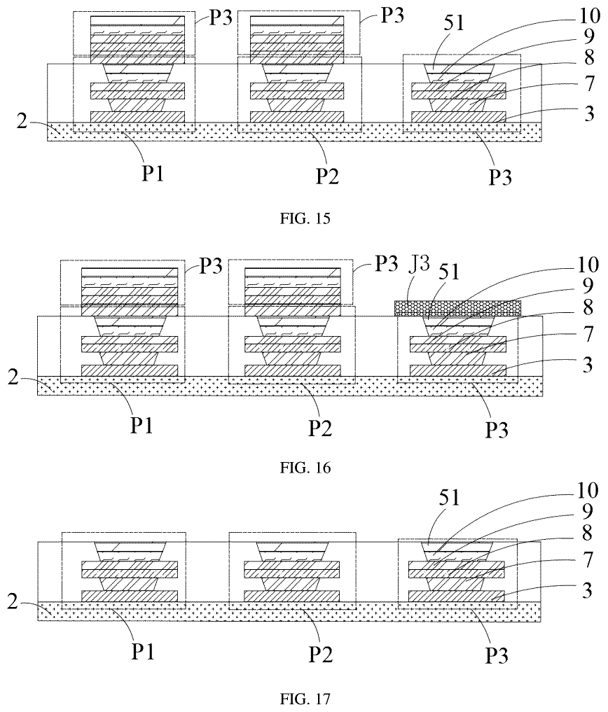

The second photoresist J2 is removed. And the light-emitting material layer 7, the second electrode layer 8, the light-emitting layer 9, the protective layer 10 and the inorganic encapsulation part of the second sub-pixel P2 are formed on each of a side of the inorganic encapsulation part of the first sub pixel away from the light-emitting material layer 7, a side of the inorganic encapsulation part of the second sub pixel away from the light-emitting material layer 7, and another pixel opening, as shown in FIG. 15.

A third photoresist J3 is formed on a side of the inorganic encapsulation part in the pixel opening provided with only the third sub-pixel unit P3 away from the light-emitting material layer 7, as shown in FIG. 16.

The light-emitting material layer 7, the second electrode layer 8, the light-adjusting layer 9, the protective layer 10 and the inorganic encapsulation part of the third sub-pixel unit P3 in the pixel opening not covered by the third photoresist J3 are etched and removed, and the third photoresist J3 is removed, as shown in FIG. 17.

The second slot K2 is formed at the pixel definition layer 4 between at least partially adjacent first sub-pixel unit P1, second sub-pixel unit P2 and third sub-pixel unit P3.

The organic encapsulation layer 52 is formed on a side of each inorganic encapsulation part away from the light-emitting material layer 7, and part of the organic encapsulation layer 52 is filled into the second slot K2 to be communicated with the organic layer.

The present disclosure also provides a display device, including: a display panel of any of the above embodiments.

Therefore, the display device provided in the embodiment of the present disclosure has the technical effect of the technical solution of the display panel in any of the above embodiments, and the same or corresponding structure and the explanation of the terms in the above embodiments are not repeated herein.

The embodiments of the present disclosure provide a display device that may be applied to a mobile phone or any electronic product with a display function, including but not limited to the following categories: televisions, notebook computers, desktop displays, tablet computers, digital cameras, smart bracelets, smart glasses, vehicle displays, medical equipment, industrial control equipment, touch interactive terminals, etc., and the embodiments of the present disclosure do not make special restrictions on this.

It should also be noted that the exemplary embodiments mentioned in the present disclosure describe some methods or systems based on a series of steps or devices. However, the present disclosure is not limited to the sequence of the above steps, that is, the steps may be executed in the order mentioned in the embodiment, or may be different from the order in the embodiment, or several steps may be executed simultaneously.

What is claimed is:

1. A display panel, comprising:
an array substrate;
an organic layer arranged on a side of the array substrate;
a pixel definition layer arranged on a side of the organic layer away from the array substrate and having a slot breaking therethrough;
an encapsulation layer arranged on a side of the pixel definition layer away from the array substrate, wherein the encapsulation layer comprises an organic encapsulation layer, and the organic encapsulation layer and the organic layer are communicated with each other through the slot.

2. The display panel of claim 1, wherein the encapsulation layer comprises a first inorganic encapsulation layer, the organic encapsulation layer and a second inorganic encapsulation layer stacked along a thickness direction of the display panel, and the first inorganic encapsulation layer is close to the organic layer relative to the second inorganic encapsulation layer;
an orthographic projection of the first inorganic encapsulation layer on the array substrate are staggered with an orthographic projection of the slot on the array substrate.

3. The display panel of claim 1, wherein the pixel definition layer comprises at least one inorganic material layer.

4. The display panel of claim 2, further comprising a first electrode layer arranged on a side of the organic layer away from the array substrate, wherein the first electrode layer comprises a plurality of first electrode blocks insulated from each other.

5. The display panel of claim 4, wherein the pixel definition layer has a pixel opening for exposing at least part of one of the first electrode blocks.

6. The display panel of claim 2, wherein the display panel has a display area and a frame area adjacent to the display area, and the organic layer, the pixel definition layer and the encapsulation layer extend from the display area to the frame area;
in the frame area, the pixel definition layer is provided with a first slot communicating the organic encapsulation layer with the organic layer;
the organic encapsulation layer is partially filled into the first slot.

7. The display panel of claim 6, wherein the organic layer comprises a planarization layer; or, the organic layer comprises a planarization layer and a hole layer stacked along the thickness direction of the display panel.

8. The display panel of claim 6, wherein the first slot is arranged around the display area.

9. The display panel of claim 8, wherein the first slot in the frame area is of a continuous annular structure; or, the pixel definition layer comprises a plurality of first slots spaced apart in the frame area.

10. The display panel of claim 6, wherein an orthographic projection of the first inorganic encapsulation layer located in the frame area on the array substrate and an orthographic projection of the first slot on the array substrate are staggered.

11. The display panel of claim 4, wherein the display panel has a display area and a frame area adjacent to the display area;
in the display area, the pixel definition layer is provided with a second slot for communicating the organic encapsulation layer and the organic layer, and an orthographic projection of the second slot on the array substrate and an orthographic projection of the pixel opening on the array substrate are staggered;
the organic encapsulation layer is partially filled into the second slot.

12. The display panel of claim 11, wherein the display panel has a display area and a frame area adjacent to the display area;
an isolation portion is provided on a side of an organic layer of the pixel definition layer away from the array substrate, and the second slot extends across the isolation portion to be communicated with the organic layer.

13. The display panel of claim 12, wherein along the thickness direction of the display panel, a cross-section of the isolation portion is in at least one of an I-shape and a T-shape.

14. The display panel of claim 11, further comprising a plurality of sub-pixel units with different colors, wherein the sub-pixel units are located in respective pixel openings, each sub-pixel unit comprises the first electrode block, a light-emitting material layer and a second electrode layer that are stacked, and the second slot is arranged between at least part of adjacent sub-pixel units.

15. The display panel of claim 14, wherein, at least in the display area, the first inorganic encapsulation layer comprises a plurality of inorganic encapsulation parts spaced apart with each other and corresponding to the sub-pixel units, and an orthographic projection of the inorganic encapsulation parts on the array substrate and an orthographic projection of the second slot on the array substrate are staggered.

16. The display panel of claim 15, wherein at least part of the inorganic encapsulation portion is arranged between two adjacent isolation portions.

17. The display panel of claim 15, wherein at least part of the second slot is arranged to form an enclosed annular construction to receive a respective sub-pixel unit.

18. The display panel of claim 17, wherein the pixel definition layer comprises only one second slot arranged to form an enclosed annular construction to receive a respective sub-pixel unit.

19. The display panel of claim 15, wherein at least part of the second slot is arranged around part of a respective sub-pixel unit.

20. A display device comprising the display panel of claim 1.
